(19) United States
(12) Patent Application Publication
(10) Pub. No.: US 2011/0175981 A1
(43) Pub. Date: Jul. 21, 2011

(54) 3D COLOR IMAGE SENSOR

(76) Inventors: Chun-Hung Lai, Taichung City (TW); Chi-Xiang Tseng, Hsinchu City (TW); Chen-Wei Lu, Hsinchu County (TW); I-Hsiu Chen, Taipei City (TW)

(21) Appl. No.: 12/689,905

(22) Filed: Jan. 19, 2010

(51) Int. Cl. H04N 15/00

(52) U.S. Cl. 348/46; 348/164; 348/E05.09; 348/E13.074; 348/E15.001

(57) ABSTRACT

A 3D color image sensor and a 3D optical imaging system including the 3D color image sensor are provided. The 3D color image sensor includes a semiconductor substrate, having a plurality of first photodiodes and a plurality of second photodiodes, and a wiring layer formed under the first photodiodes and the second photodiodes. A light filter array layer is disposed on the first and the second photodiodes, having a plurality of color filter patterns and infrared (IR) light filter patterns, wherein each of the IR light filter patterns receives depth information of 3D color image of an object and corresponds to the first photodiode, and each of the color filter patterns receives color image information of 3D color image of the object and corresponds to the second photodiode.

### BACKGROUND OF THE INVENTION

1. Field of the Invention

The invention relates to a sensor and more particularly to a sensor receiving depth and color image information of 3D color image of an object.

2. Description of the Related Art

Three dimensional (3D) optical imaging systems such as 3D cameras that are capable of providing distance measurements to objects that they image are used for many different applications. For example, profile inspection of manufactured goods, computer-aided design (CAD) verification, geographic surveying and object imaging.

3D cameras contain a light source for illuminating a scene being imaged. To image a scene and determine distances from the camera to objects in the scene, the scene is generally illuminated with a train of light pulses radiated from a light source. Light from the light pulse that is reflected from an object in the scene is imaged on a photosensitive surface of the 3D cameras. The time elapsed between radiating a light pulse from the light source to the object in the scene and the light pulse being reflected back to the camera is used to determine the distance from the 3D camera to the object.

In general, the conventional 3D optical imaging systems use two sensors for generating 3D images. One sensor is a depth sensor for determining distances from the camera to objects in a scene and generating a 3D depth map of the objects. The other sensor is an image sensor for collecting image information of the object in a scene and generating a picture of the objects. Because conventional 3D optical imaging systems need two sensors to receive depth information and image information separately, algorithms for signal processors of conventional 3D optical imaging systems for processing data from the two sensors are complicated. Meanwhile, for conventional 3D optical imaging systems applied to real time 3D image games, small finger movements from users may not be detected by sensors therein, due to low motion sensitivity and low signal-to-noise ratio (SNR) of the two sensors.

Therefore, a 3D color image sensor receiving depth and color image information of 3D color image of an object is desired.

### BRIEF SUMMARY OF THE INVENTION

A 3D color image sensor is provided. The 3D color image sensor receives depth information and color image information of 3D color image of an object. An exemplary embodiment of the 3D color image sensor comprises a semiconductor substrate, having a plurality of first photodiodes and a plurality of second photodiodes. A wiring layer is formed under the first photodiodes and the second photodiodes in the semiconductor substrate. A light filter array layer is disposed on the first photodiodes and the second photodiodes, having a plurality of color filter patterns and a plurality of infrared (IR) light filter patterns, wherein each of the IR light filter patterns receives depth information of 3D color image of an object and corresponds to the first photodiode, and each of the color filter patterns receives color image information of 3D color image of the object and corresponds to the second photodiode.

Further, a 3D optical imaging system is provided. An exemplary embodiment of the 3D optical imaging system comprises a light source for illuminating an object. A 3D color image sensor receives depth information and color image information of 3D color image of the object and converting the depth information and color image information into electrical signals. A signal processor processes the electrical signals from the 3D color image sensor to generate 3D color image of the object. The 3D color image sensor comprises a semiconductor substrate, having a plurality of first photodiodes and a plurality of second photodiodes, and a wiring layer formed under the first photodiodes and the second photodiodes; and a light filter array layer disposed on the first photodiodes and the second photodiodes, having a plurality of color filter patterns and a plurality of (infrared) IR light filter patterns, wherein each of the IR light filter patterns receives the depth information of 3D color image of the object and corresponds to the first photodiode, and each of the color filter patterns receives the color image information of 3D color image of the object and corresponds to the second photodiode.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1A is a schematic plane view of a light filter array layer according to one embodiment of the invention;

FIG. 1B is a schematic plane view of a light filter array layer according to another embodiment of the invention; and

FIG. 2 is a schematic cross section of a 3D color image sensor along a dotted line 2-2′ of FIG. 1A according to one embodiment of the invention.

### DETAILED DESCRIPTION OF INVENTION

The following description is of the best-contemplated mode of carrying out the invention. This description is made for the purpose of illustrating the general principles of the invention and should not be taken in a limiting sense. The scope of the invention is best determined by reference to the appended claims.

An exemplary embodiment of the invention provides a 3D color image sensor for receiving depth information and color image information of 3D color image of objects, wherein the objects are imaged by a 3D optical imaging system having the 3D color image sensor therein. The 3D color image sensor includes a semiconductor substrate, having a plurality of first photodiodes and a plurality of second photodiodes. The first photodiodes are used for receiving the depth information of 3D color image of the objects. The second photodiodes are used for receiving the color image information of 3D color image of the objects. A wiring layer is formed under the first photodiodes and the second photodiodes in the semiconductor substrate. The wiring layer includes a plurality of circuit areas which correspond to the first photodiodes and the second photodiodes, respectively. A light filter array layer is disposed over the first photodiodes and the second photodiodes on the semiconductor substrate, having a plurality of color filter patterns and a plurality of infrared (IR) light filter patterns. The color filter patterns and the IR light filter patterns are arranged in order to form an array. Each IR light filter pattern receives the depth information of 3D color image of the object and corresponds to the first photodiode. Each color filter pattern receives the color image information of 3D color image of the object and corresponds to the second photodiode.

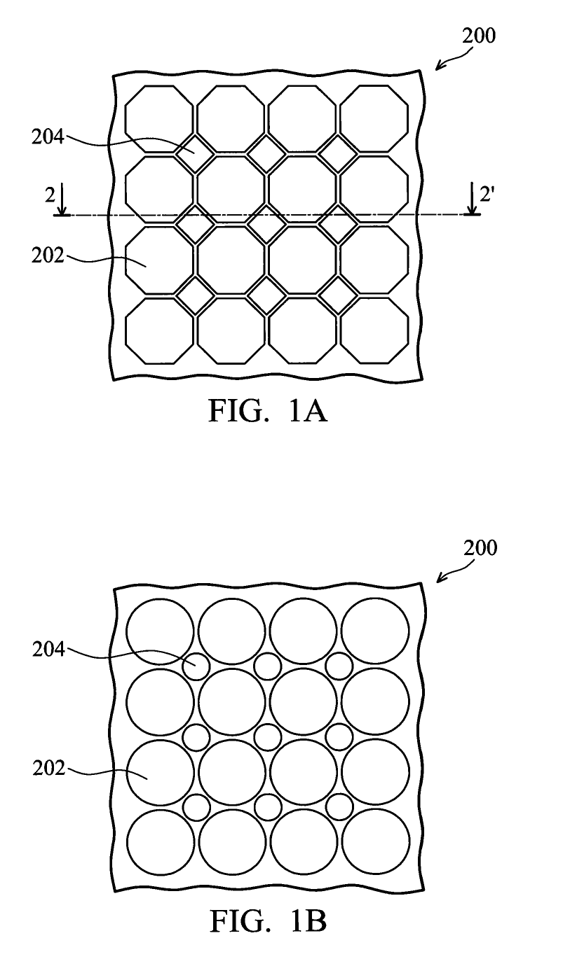

Referring to FIG. 1A, a plane view of a light filter array layer 200 according to an embodiment of the invention is shown. The light filter array layer 200 includes a plurality of IR light filter patterns 202 and a plurality of color filter patterns 204. In an embodiment, the shape of IR light filter pattern 202 may be an octagon and the shape of color filter pattern 204 may be a quadrangle. Each color filter pattern 204 is arranged to be adjacent to four IR light filter patterns 202. The IR light filter pattern 202 is formed from a black photoresist to permit an IR light to pass through. The color filter pattern 204 is formed from a color resist to permit a visual light to pass through. The color filter pattern 204 can be a red, green or blue color filter to permit a red, green or blue light to pass through, respectively. In an embodiment, the red, green and blue color filter patterns 204 are arranged as closely as possible, for example three red, green and blue color filter patterns 204 can be arranged as a triangle.

Referring to FIG. 1B, a plane view of a light filter array layer 200 according to another embodiment of the invention is shown. In this embodiment, the shape of IR light filter pattern 202 and the shape of color filter pattern 204 can be circular. The materials and the arrangement of the IR light filter patterns 202 and the color filter patterns 204 may be the same as the above mentioned embodiment. It is noted that, according to an exemplary embodiment of the invention, a size of the IR light filter pattern 202 is larger than a size of the color filter pattern 204. A ratio of the size of the IR light filter pattern 202 to the size of the color filter pattern 204 greater than 10 is preferred.

The light filter array layer 200 consists of the IR light filter patterns 202 and the color filter patterns 204, wherein the color filter patterns 204 may be a red, green or blue color filter. A pattern layout of the light filter array layer 200 may be shown as, but is not limited to, the pattern layout of FIG. 1A or FIG. 1B. The IR light filter patterns 202 and the color filter patterns 204 of the light filter array layer 200 can be arranged flexibly and efficiently according to the 3D color image sensor.

An exemplary embodiment of the invention provides a 3D optical imaging system including the 3D color image sensor therein. In general, the 3D optical imaging system includes a light source for providing a train of light pulses, preferably IR light pulses, to illuminate the objects being imaged by the 3D optical imaging system. IR light from the light source is reflected by the objects and received by the IR light filter patterns 202 of the 3D color image sensor for generating a 3D depth map of the objects. Meanwhile, visual light from natural light or another light source of the 3D optical imaging system is also reflected by the objects and received by the color filter patterns 204 of the same 3D color image sensor for generating a color image of the objects. According to an embodiment of the invention, both depth information and color image information of 3D color image of the objects are received by a single 3D color image sensor. Thus, algorithms of a signal processor for processing data from the 3D color image sensor of the invention may be designed simpler than that of the conventional 3D optical imaging system using two sensors to receive the depth information and the color image information of 3D color image of the objects. Moreover, according to an embodiment of the invention, a ratio of the size of the IR light filter pattern 202 to the size of the color filter pattern 204 is greater than 10. Thus, when the 3D color image sensor of the invention is applied to real time 3D image games, small finger movements from users may be detected due to the high motion sensitivity to the movement of objects due to larger sized and greater number of IR light filter patterns 202 of the 3D color image sensor of the invention.

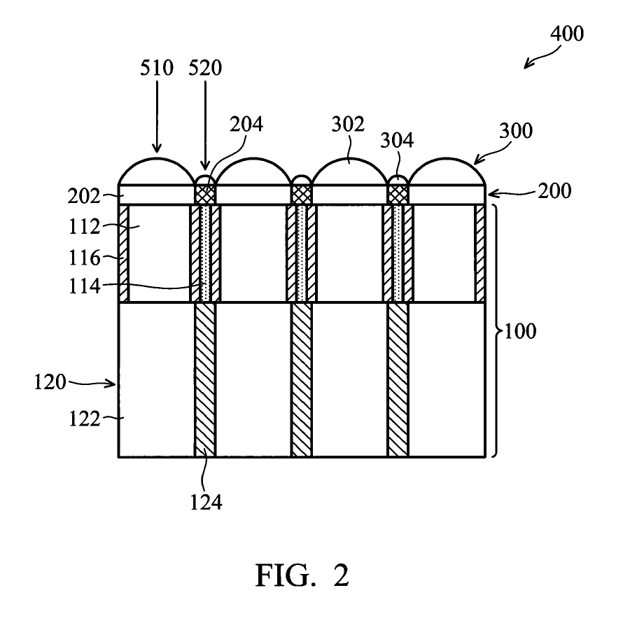

Then, referring to FIG. 2, a cross section of a 3D color image sensor 400 along a dotted line 2-2′ of FIG. 1A according to an embodiment of the invention is shown. The 3D color image sensor 400 includes a semiconductor substrate 100 such as a silicon substrate or other semiconductor substrates. The semiconductor substrate 100 has a plurality of first photodiodes 112 and a plurality of second photodiodes 114 formed therein. The first photodiodes 112 and the second photodiodes 114 are isolated by an insulator 116. The insulator 116 may be shallow trench isolations (STI) formed between the first photodiode 112 and the second photodiode 114. A light filter array layer 200 is disposed over the first photodiodes 112 and the second photodiodes 114 on the semiconductor substrate 100. The light filter array layer 200 includes a plurality of IR light filter patterns 202 and a plurality of color filter patterns 204. The IR light filter patterns 202 and the color filter patterns 204 are arranged in order to form an array such as the light filter array layer 200 of FIG. 1A or FIG. 1B. Each IR light filter pattern 202 receives the depth information of 3D color image of the objects, i.e. IR light reflected from the objects and corresponds to the first photodiode 112. Each color filter pattern 204 receives the color image information of 3D color image of the object, i.e. visual light reflected from the objects and corresponds to the second photodiode 114t.

A wiring layer 120 is formed under the first photodiodes 112 and the second photodiodes 114 in the semiconductor substrate 100. The wiring layer 120 consists of several metal layers and several dielectric layers disposed between the metal layers, which can be formed by semiconductor integrated circuit processing technology as known in the art. In order to simplify the diagram, the metal layers and the dielectric layers are not depicted in FIG. 2. The wiring layer 120 includes a plurality of circuit areas 122 and 124 corresponding to the first photodiodes 112 and the second photodiodes 114, respectively. IR light that is reflected from the objects, represented by the arrow 510, passes through the IR light filter patterns 202 and the first photodiodes 112. The IR light 510 is converted by the first photodiodes 112 into an electrical signal and the electrical signal is then transmitted to the circuit areas 122. Accordingly, the IR light 510 reflected from the objects is converted into the electrical signal of the depth information of 3D color image of the objects which represents the distances from the objects to the 3D optical imaging system. Meanwhile, visual light that is reflected from the objects, represented by the arrow 520, passes through the color filter patterns 204 and the second photodiodes 114. Then, the visual light 520 is converted by the second photodiodes 114 into another electrical signal, wherein the electrical signal is also transmitted to the circuit areas 124. Accordingly, the visual light 520 reflected from the objects is converted into the electrical signal of the color image information of 3D color image of the objects being imaged by the 3D optical imaging system.

In an embodiment, the 3D color image sensor 400 may further include a micro-lens array 300 disposed over the light filter array layer 200. The micro-lens array 300 has a plurality of first micro-lenses 302 corresponding to the IR light filter patterns 202 and a plurality of second micro-lenses 304 corresponding to the color filter patterns 204. The micro-lens array 300 enhances the amount of IR light 510 and visual light 520 received by the IR light filter patterns 202 and the color filter patterns 204, respectively. In an embodiment, a size of the first micro-lens 302 is substantially the same as the size of the IR light filter pattern 202. A size of the second micro-lens 304 is substantially the same as the size of the color filter pattern 204. Moreover, the micro-lens array 300 may have a pattern layout substantially the same as a pattern layout of the light filter array layer 200, i.e. the first micro-lenses 302 and the second micro-lenses 304 can be arranged in the same way as the arrangement of the IR light filter patterns 202 and the color filter patterns 204 as shown in FIG. 1A or FIG. 1B.

In general, a surface of the semiconductor substrate 100 having circuits formed thereon is referred to as a front side and a surface opposite to the front side is referred to as a back side. If light illuminates the back side of the sensor, the sensor is referred to as a backside illumination (BSI) sensor. According to an embodiment, the surface of the 3D color image sensor for receiving the IR light 510 and the visual light 520 is opposite to the surface having the circuit areas 122 and 124 thereon. Thus, in an embodiment of the invention, the 3D color image sensor may be a backside illumination (BSI) sensor. The BSI 3D color image sensor has a large space for disposing wiring layers so that the light receiving efficiency thereof is not reduced. Thus, according to an embodiment of the invention, the BSI 3D color image sensor may have a large circuit layout for receiving great amounts of depth information and great amounts of color image information of 3D color image of the objects.

According to the aforementioned embodiments, the 3D color image sensor provides depth information and color image information of 3D color image of the objects simultaneously. Therefore, algorithms of a signal processor for processing data from the 3D color image sensor of the invention may be designed simpler than that of the conventional 3D optical imaging system using two sensors to receive the depth information and the color image information. Meanwhile, because the size of the IR light filter pattern is larger than that of the color filter pattern according to an embodiment of the invention, the sensitivity of the 3D color image sensor to IR light can be enhanced. Therefore, when the 3D color image sensor of the invention is applied to real time 3D image games, small finger movements from users is detected by the 3D color image sensor due to high motion sensitivity. Moreover, the pattern layout of the light filter array layer of the 3D color image sensor can be adjusted, such that the 3D color image sensor can be used flexibly and efficiently.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A three dimensional (3D) color image sensor, comprising:
a semiconductor substrate, having a plurality of first photodiodes and a plurality of second photodiodes, and a wiring layer formed under the first photodiodes and the second photodiodes; and
a light filter array layer disposed on the first photodiodes and the second photodiodes, having a plurality of color filter patterns and a plurality of (infrared) IR light filter patterns,
wherein each of the IR light filter patterns receives depth information of 3D color image of an object and corresponds to the first photodiode, and each of the color filter patterns receives color image information of 3D color image of the object and corresponds to the second photodiode.

2. The 3D color image sensor as claimed in claim 1, wherein the color filter patterns and the IR light filter patterns are arranged so that each of the color filter patterns are adjacent to four IR light filter patterns.

3. The 3D color image sensor as claimed in claim 1, wherein a ratio of a size of the IR light filter pattern to a size of the color filter pattern is greater than 10.

4. The 3D color image sensor as claimed in claim 1, wherein the color image information of 3D color image of the object is provided from a visual light reflected from the object.

5. The 3D color image sensor as claimed in claim 1, wherein the depth information of 3D color image of the object is provided from an IR light reflected from the object.

6. The 3D color image sensor as claimed in claim 1, further comprising a plurality of insulators individually disposed between the first photodiodes and the second photodiodes.

7. The 3D color image sensor as claimed in claim 1, wherein the wiring layer comprises a plurality of circuit areas which correspond to the first photodiodes and the second photodiodes, respectively.

8. The 3D color image sensor as claimed in claim 7, wherein the circuit areas corresponding to the first photodiodes provide data for generating a 3D depth map of the object, and the circuit areas corresponding to the second photodiodes provide data for generating a color image of the object.

9. The 3D color image sensor as claimed in claim 1, further comprising a micro-lens array disposed over the light filter array layer.

10. The 3D color image sensor as claimed in claim 9, wherein the micro-lens array comprises a plurality of first micro-lenses corresponding to the IR light filter patterns and a plurality of second micro-lenses corresponding to the color filter patterns.

11. The 3D color image sensor as claimed in claim 10, wherein a size of the first micro-lens is the same as a size of the IR light filter pattern.

12. The 3D color image sensor as claimed in claim 10, wherein a size of the second micro-lens is the same as a size of the color filter pattern.

13. The 3D color image sensor as claimed in claim 1, wherein the IR light filter pattern is formed from a black photoresist and an IR light passes through the IR light filter pattern.

14. The 3D color image sensor as claimed in claim 1, wherein a shape of the color filter pattern and the IR light filter pattern is circular.

15. The 3D color image sensor as claimed in claim 1, wherein a shape of the color filter pattern is a quadrangle and a shape of the IR light filter pattern is an octagon.

16. The 3D color image sensor as claimed in claim 1, wherein the 3D color image sensor is a backside illumination sensor.

17. A three dimensional (3D) optical imaging system, comprising:
a light source for illuminating an object;
a 3D color image sensor for receiving depth information and color image information of 3D color image of the object and converting the depth information and color image information into electrical signals; and
a signal processor for processing the electrical signals from the 3D color image sensor to generate 3D color image of the object,
wherein the 3D color image sensor comprises:
a semiconductor substrate, having a plurality of first photodiodes and a plurality of second photodiodes, and a wiring layer formed under the first photodiodes and the second photodiodes; and
a light filter array layer disposed on the first photodiodes and the second photodiodes, having a plurality of color filter patterns and a plurality of (infrared) IR light filter patterns, wherein each of the IR light filter patterns receives the depth information of 3D color image of the object and corresponds to the first photodiode, and each of the color filter patterns receives the color image information of 3D color image of the object and corresponds to the second photodiode.

18. The 3D optical imaging system as claimed in claim 17, wherein the light source provides an IR light to illuminate the object, and the IR light is reflected by the object to generate the depth information of 3D color image of the object.

19. The 3D optical imaging system as claimed in claim 17, further comprising a visual light from natural light to illuminate the object, wherein the visual light is reflected by the object to generate the color image information of 3D color image of the object.

20. The 3D optical imaging system as claimed in claim 17, wherein a ratio of a size of the IR light filter pattern to a size of the color filter pattern is greater than 10.
